(19) United States
(12) Patent Application Publication
(10) Pub. No.: US 2025/0151386 A1
(43) Pub. Date: May 8, 2025

(54) COMPLEMENTARY FIELD EFFECT TRANSISTOR (CFET) CIRCUITS WITH DIRECT VERTICAL CONNECTORS AND METHODS FOR MAKING THE SAME

(71) Applicant: QUALCOMM Incorporated, San Diego, CA (US)

(72) Inventors: Shreesh NARASIMHA, Charlotte, NC (US); Yan SUN, San Diego, CA (US)

(21) Appl. No.: 18/503,839

(22) Filed: Nov. 7, 2023

(51) Int. Cl. H01L 27/092; H01L 21/822; H01L 21/8238; H01L 29/06; H01L 29/417; H01L 29/423; H01L 29/66; H01L 29/775

(52) U.S. Cl. CPC H10D 84/856; H10D 30/014; H10D 30/43; H10D 30/6729; H10D 30/6735; H10D 62/121; H10D 84/0186; H10D 84/038; H10D 88/01

(57) ABSTRACT

Disclosed are complementary field effect transistor (CFET) circuits with direct vertical connectors and methods for making the same. In an aspect, a semiconductor structure comprises a first field effect transistor (FET) of a first charge carrier type, comprising first and second source/drain (S/D) regions and one or more channels that electrically connect the first and second S/D regions through a first gate structure; a second FET of a second charge carrier type, disposed above the first FET in a Z direction and comprising third and fourth S/D regions and one or more channels that electrically connect the third and fourth S/D regions through a second gate structure; and a vertical connector extending in the Z direction from a top surface of the first S/D region to a bottom surface of the third S/D region and electrically coupling the first S/D region to the third No errors found.S/D region.

### BACKGROUND OF THE DISCLOSURE

### 1. Field of the Disclosure

Aspects of the disclosure relate generally to high performance devices, and more specifically to semiconductor structures for complementary field effect transistors (CFETs).

### 2. Description of the Related Art

Integrated circuit technology has achieved great strides in advancing computing power through miniaturization components such as semiconductor transistors. The progression of semiconductors have progressed from bulk substrates and planar CMOS, FinFETs, nanowires or nanoribbons (also called nanosheets), to nanowire or nanoribbon 3D stacking. The semiconductor technologies have largely been based on silicon. However, fabrication of transistors based on silicon may be problematic when it comes to further reduction in scaling. e.g., to few nanometers. Accordingly, there is a need for systems, apparatus, and methods that overcome the deficiencies of conventional devices including the methods, system and apparatus provided herein.

### SUMMARY

The following presents a simplified summary relating to one or more aspects disclosed herein. Thus, the following summary should not be considered an extensive overview relating to all contemplated aspects, nor should the following summary be considered to identify key or critical elements relating to all contemplated aspects or to delineate the scope associated with any particular aspect. Accordingly, the following summary has the sole purpose to present certain concepts relating to one or more aspects relating to the mechanisms disclosed herein in a simplified form to precede the detailed description presented below.

In an aspect, a semiconductor structure includes a first field effect transistor (FET) of a first charge carrier type, comprising a first source/drain (S/D) region, a second S/D region, and a first set of one or more channels that electrically connect the first S/D region to the second S/D region through a first gate structure; a second FET of a second charge carrier type, disposed above the first FET in a Z direction and comprising a third S/D region disposed above the first S/D region, a fourth S/D region, and a second set of one or more channels that electrically connect the third S/D region to the fourth S/D region through a second gate structure; and a vertical connector extending in the Z direction from a top surface of the first S/D region to a bottom surface of the third S/D region and electrically coupling the first S/D region to the third S/D region.

In an aspect, a method of fabricating a semiconductor structure includes providing a first FET of a first charge carrier type, comprising providing a first S/D region, providing a second S/D region, and providing a first set of one or more channels that electrically connect the first S/D region to the second S/D region through a first gate structure; providing a second FET of a second charge carrier type, disposed above the first FET in a Z direction, comprising providing a third S/D region disposed above the first S/D region, providing a fourth S/D region, and providing a second set of one or more channels that electrically connect the third S/D region to the fourth S/D region through a second gate structure; and providing a vertical connector extending in the Z direction from a top surface of the first S/D region to a bottom surface of the third S/D region and electrically coupling the first S/D region to the third S/D region.

Other objects and advantages associated with the aspects disclosed herein will be apparent to those skilled in the art based on the accompanying drawings and detailed description.

### BRIEF DESCRIPTION OF THE DRAWINGS

The accompanying drawings are presented to aid in the description of various aspects of the disclosure and are provided solely for illustration of the aspects and not limitation thereof.

FIG. 1 illustrates a nanosheet field effect transistor (FET).

FIG. 2A and FIG. 2B show plan views of an example integrated circuit that illustrates an offset vertical connector (OVC).

FIG. 2C is a cross-sectional view of a CFET having an OVC.

FIG. 3A and FIG. 3B show plan views of an example integrated circuit that illustrates a direct vertical connector (DVC), according to aspects of the disclosure.

FIG. 3C is a cross-sectional view of a CFET having a DVC, according to aspects of the disclosure.

FIG. 4 is a cross-sectional view of an integrated circuit comprising a substrate upon which a gate structure with small, discontinuous epitaxial (SDE) structures has been fabricated, according to aspects of the disclosure.

FIG. 5 is a flowchart showing a portion of a simplified wafer process for fabricating the structure shown in FIG. 4, according to aspects of the disclosure.

FIG. 6A, FIG. 6B, and FIG. 6C are cross-sectional views of integrated circuit during steps of a process for fabricating a DVC between FETs in a CFET stack, according to aspects of the disclosure.

FIG. 7A, FIG. 7B, FIG. 7C, and FIG. 7D are cross-sectional views of integrated circuit during steps of another process for fabricating a DVC between FETs in a CFET stack, according to aspects of the disclosure.

FIG. 8 is a flowchart of an example process associated with fabrication of CFET circuits with direct vertical connectors, according to aspects of the disclosure.

FIG. 9 illustrates a mobile device, according to aspects of the disclosure.

FIG. 10 illustrates various electronic devices that may be integrated with any of the integrated circuits described herein, according to aspects of the disclosure.

In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

Disclosed are complementary field effect transistor (CFET) circuits with direct vertical connectors and methods for making the same. In an aspect, a semiconductor structure comprises a first field effect transistor (FET) of a first charge carrier type, comprising a first source/drain (S/D) region, a second S/D region, and a first set of one or more channels that electrically connect the first S/D region to the second S/D region through a first gate structure; a second FET of a second charge carrier type, disposed above the first FET in a Z direction and comprising a third S/D region disposed above the first S/D region, a fourth S/D region, and a second set of one or more channels that electrically connect the third S/D region to the fourth S/D region through a second gate structure; and a vertical connector extending in the Z direction from a top surface of the first S/D region to a bottom surface of the third S/D region and electrically coupling the first S/D region to the third S/D region.

The semiconductor structures disclosed herein provide at least the advantage of enabling a highly scaled 3T CFET logic image with sufficient metal layer zero (MO) resources to design efficient logic libraries, enabled by multiple unique middle-of-line (MOL) structural features. These MOL structural features include, but are not limited to, a direct vertical connector (DVC) that connects the S/D of the top and bottom FETs directly without any area loss, i.e., no offset in the Y direction (i.e., the “height” of a standard cell) is required. This enables an additional 20% area scaling capability for the CFET architecture, makes available more upper and lower contact points to the CFET source, drain, and gate structures, and reduces parasitic capacitance compared to an offset vertical connector (OVC) located to the side of the CFET stack rather than between the FETs of the CFET stack. The DVC is accomplished by the use of a small, discontinuous EPI (SDE) structure on the top FET of the CFET stack.

Aspects of the disclosure are provided in the following description and related drawings directed to various examples provided for illustration purposes. Alternate aspects may be devised without departing from the scope of the disclosure. Additionally, well-known elements of the disclosure will not be described in detail or will be omitted so as not to obscure the relevant details of the disclosure.

The words “exemplary” and/or “example” are used herein to mean “serving as an example, instance, or illustration.” Any aspect described herein as “exemplary” and/or “example” is not necessarily to be construed as preferred or advantageous over other aspects. Likewise, the term “aspects of the disclosure” does not require that all aspects of the disclosure include the discussed feature, advantage or mode of operation.

Those of skill in the art will appreciate that the information and signals described below may be represented using any of a variety of different technologies and techniques. For example, data, instructions, commands, information, signals, bits, symbols, and chips that may be referenced throughout the description below may be represented by voltages, currents, electromagnetic waves, magnetic fields or particles, optical fields or particles, or any combination thereof, depending in part on the particular application, in part on the desired design, in part on the corresponding technology, etc.

Further, many aspects are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, the sequence(s) of actions described herein can be considered to be embodied entirely within any form of non-transitory computer-readable storage medium having stored therein a corresponding set of computer instructions that, upon execution, would cause or instruct an associated processor of a device to perform the functionality described herein. Thus, the various aspects of the disclosure may be embodied in a number of different forms, all of which have been contemplated to be within the scope of the claimed subject matter. In addition, for each of the aspects described herein, the corresponding form of any such aspects may be described herein as, for example, “logic configured to” perform the described action.

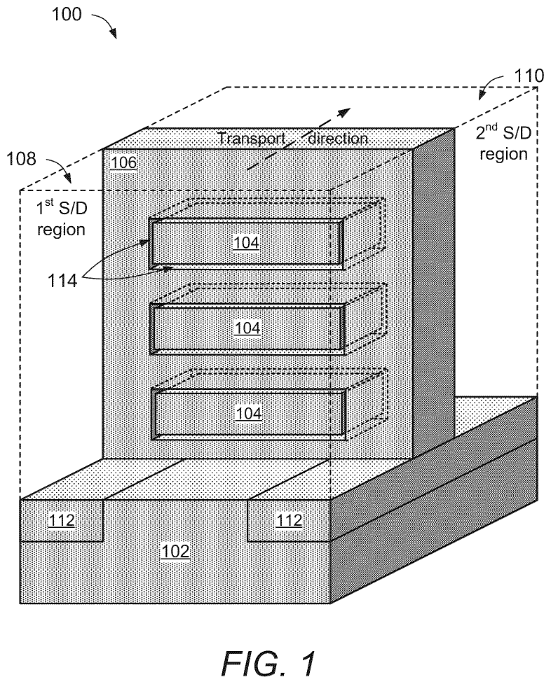

FIG. 1 illustrates a nanosheet field effect transistor (FET) 100. The nanosheet FET 100 shown in FIG. 1 is built upon a silicon substrate 102 and comprises a set of three nanosheets 104 that extend through a gate-all-around gate (GAA) structure 106. One end of the three nanosheets 104 are electrically connected together by a first, heavily-doped epitaxial (EPI) structure (not shown) to form a first source/drain (S/D) region 108, and the other end of the three nanosheets 104 are electrically connected together by a second, heavily doped EPI structure (also not shown) to form a second S/D region 110. The gate structure is isolated from the substrate 102 by oxide isolation regions 112. The structure can be adapted so that the substrate 102 is removed entirely, to facilitate backside connectivity. The nanosheets 104 are the channels by which the charge carrier travels through the GAA structure 106 to get from the first S/D region 108 to the second S/D region 110, and thus may be referred to herein as “nanosheet channels”. Although not shown in FIG. 1 for simplicity, the nanosheets 104 are electrically insulated from the GAA structure 106 by a dielectric layer 114 that surrounds the portions of the nanosheets 104 that go through the GAA structure 106.

For each pair of S/D regions on either side of a gate, one S/D region may operate as the source and the other S/D region may operate as the drain, or vice-versa. Generally, the term “source” is used to refer to the S/D region that is tied to the source of the charge carrier (i.e., for a PFET, the S/D region tied to VDD; for an NFET, the S/D region tied to VSS), and thus whether the first S/D region 108 or the second S/D region 110 is the source depends on the specific electrical connection made to each.

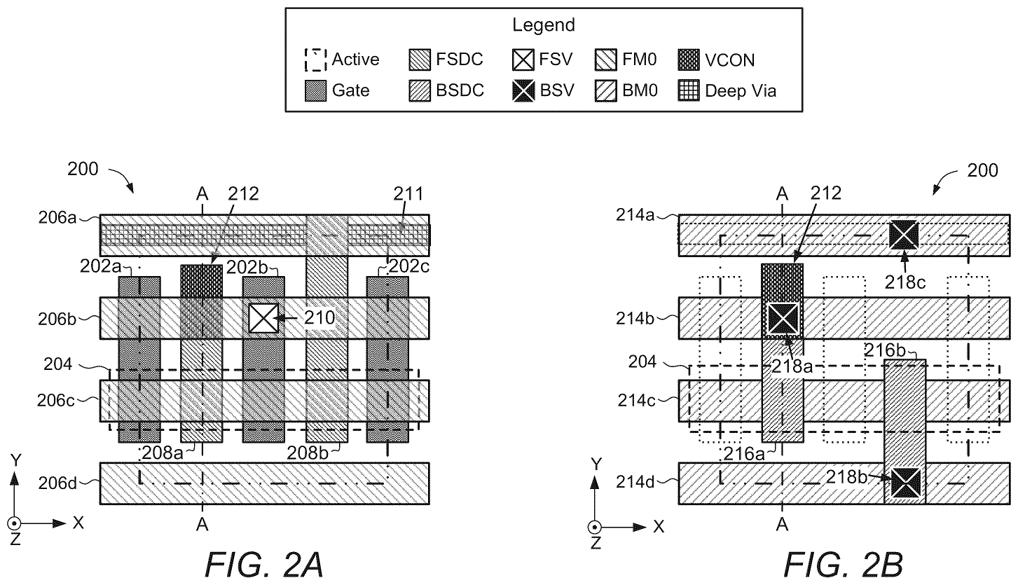

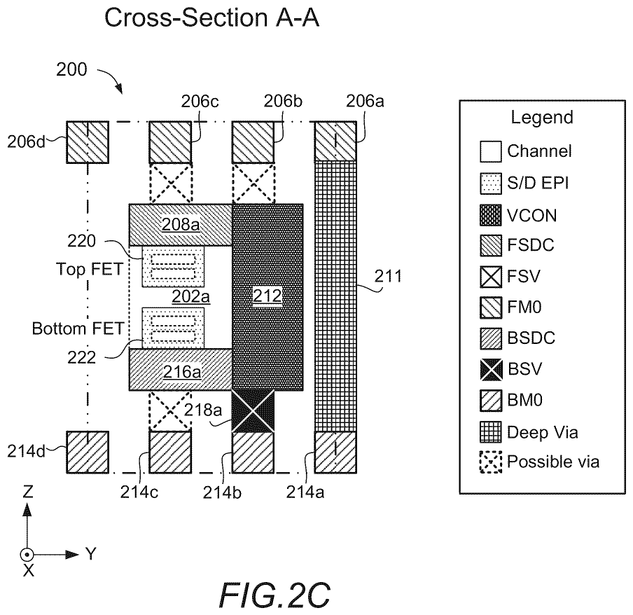

FIG. 2A and FIG. 2B show plan views of an example integrated circuit 200 that illustrates an offset vertical connector. These figures are intended to illustrate topology and connectivity. They are not intended to illustrate any specific logic function. FIG. 2A shows the frontside connections of the integrated circuit 200, as seen from the frontside, and FIG. 2B shows the backside connections of the integrated circuit 200, also as seen from the frontside. Unless otherwise specified, dashed shapes in FIG. 2B correspond to like-located frontside structures that may be accessed during the backside process for creating electrical connections. It is noted that the same architectural features are not limited to 3T topologies, but may also be applied to 2T, 2T, or other topologies.

In the example shown in FIG. 2A and FIG. 2B, the integrated circuit 200 includes a set of gate structures, labeled 202a through 202c, extending in the Y direction and spaced apart from each other in the X direction, which may be herein referred to collectively as gates 202 and individually as gate 202a. gate 202b, etc.

In the example shown in FIG. 2A and FIG. 2B, the integrated circuit 200 also includes an active region 204. Within the active region, the gates 202 contain channels that extend in the X direction through the gate structures and that electrically couple to source/drain (S/D) structures on either side of the gate structures. In some aspects, the S/D structures comprise EPI structures.

In the example shown in FIG. 2A, the integrated circuit 200 includes a set of frontside (FS) routing tracks, labeled 206a through 206d, extending in the X direction and spaced apart from each other in the Y direction, which may be herein referred to collectively as FS tracks 206 and individually as FS track 206a, FS track 206b, etc. In some aspects, each FS routing track may comprise an FS metal (FM) conductor, which may be FS metal-zero (FM0). The integrated circuit 200 also includes a set of frontside source/drain contacts (FSDCs), labeled 208a and 208b, which may be herein referred to collectively as FSDCs 208 and individually as FSDC 208a, FSDC 208b, etc. The integrated circuit 200 also includes a frontside via (FSV) 210, which may be herein referred to collectively as FSVs 210 and individually as FSV 210a, FSV 210b, etc. The integrated circuit 200 also includes a deep trench via 211 that extends in the X direction. The integrated circuit 200 also includes an offset vertical connector (OVC) 212 that extends in the Z direction.

In the example shown in FIG. 2B, the integrated circuit 200 includes a set of backside (BS) routing tracks, labeled 214a through 214d, extending in the X direction and spaced apart from each other in the Y direction, which may be herein referred to collectively as BS tracks 214 and individually as BS track 214a, BS track 214b, etc. In some aspects, each BS routing track may comprise an BS metal (BM) conductor, which may be BS metal-zero (BMO). The BS tracks 214 provide a dense BMO contact plane, shown in FIG. 2B as having the same pitch as the FM0 contact plane, but in other aspects may have a different pitch than the FM0 contact plane. The integrated circuit 200 also includes a set of backside source/drain contacts (BSDCs), labeled 216a through 218c, which may be herein referred to collectively as BSDCs 216 and individually as BSDC 216a, BSDC 216b, etc. The OVC 212 electrically connects FSDC 208a to BSDC 216a. The integrated circuit 200 also includes a set of backside vias (BSVs), labeled 218a and 218b, which may be herein referred to collectively as BSVs 218 and individually as BSV 218a, BSV 218b, etc. FIG. 2A and FIG. 2B include markings to show the locations of cross-section A-A.

FIG. 2C is a cross-sectional view of integrated circuit 200 along cut line A-A, according to aspects of the disclosure. FIG. 2C shows the relative locations of gate 202a, FS tracks 206a-d, FSDC 208a, OVC 212, BS tracks 214a-d, and BSDC 216a. As seen in FIG. 2C, gate 202a, which is a gate-all-around (GAA) gate structure, includes stacks of nanosheet channels that make up a bottom FET and a top FET. In some aspects, the bottom FET may be an NFET and the top FET may be a PFET (or vice-versa) of a CFET pair. FIG. 2C shows a first S/D region 220 associated with the top FET and a second S/D region 222 associated with the bottom FET. In this image, the gate 202a as well as the nanosheet channels of the top FET and the bottom FET are out of the plane of the cross section, and so these are depicted with dotted outlines. Similarly, elements that are optional (and included for instructive purposes), such as the locations of the possible vias, are also depicted with dotted lines.

As shown in FIG. 2C, the OVC 212 provides an electrical connection between the S/D region 220 and the S/D region 222 by way of the FSDC 208a and the BSDC 216a. It is noted, however, that the OVC 212 occupies the space between FS track 206b and BS track 214b and may extend into the space between FS track 206a and BS track 214a. The presence of the OVC 212 in or near those spaces prevents those spaces from being used for internal routing or other purposes and may constrain the placement of other structures within adjacent cells in the Y direction that share the FS track 206a and BS track 214a. In addition, because the OVC 212 extends in the Z direction from the bottom surface of the BSDC 216a to the top surface of the FSDC 208a, the OVC 212 creates additional capacitance with respect to the gate structures on either side of it in the X direction. Moreover, the presence of the OVC 212 limits how much a standard cell height can be reduced and/or imposes a bottom limit on few tracks a standard cell can have.

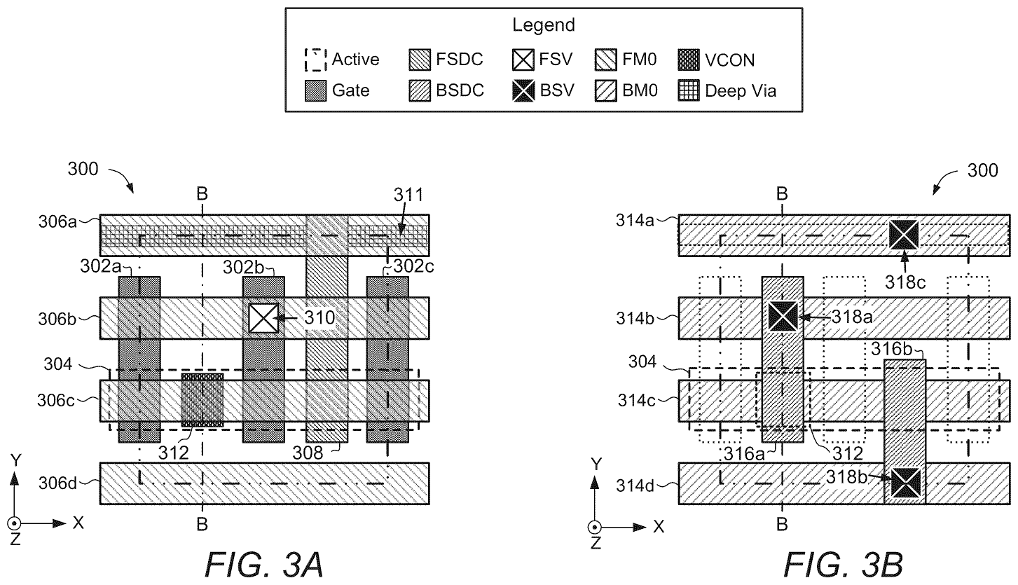

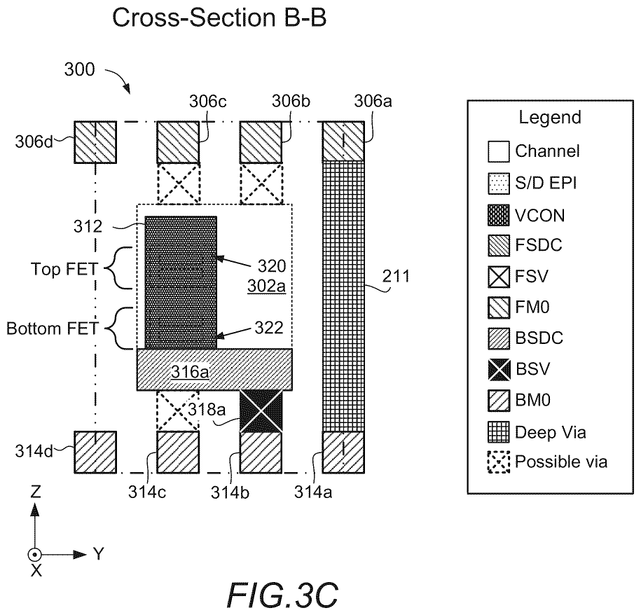

FIG. 3A and FIG. 3B show plan views of an example integrated circuit 300 that illustrates a 3T CFET logic cell topology, according to aspects of the disclosure. These figures are intended to illustrate topology and connectivity. They are not intended to illustrate any specific logic function. FIG. 3A shows the frontside connections of the integrated circuit 300, as seen from the frontside, and FIG. 3B shows the backside connections of the integrated circuit 300, also as seen from the frontside. Unless otherwise specified, dashed shapes in FIG. 3B correspond to like-located frontside structures that may be accessed during the backside process for creating electrical connections. It is noted that the same architectural features are not limited to 3T topologies, but may also be applied to 2T, 4T. or other topologies.

In the example shown in FIG. 3A and FIG. 3B, the integrated circuit 300 includes a set of gate structures, labeled 302a through 302c, extending in the Y direction and spaced apart from each other in the X direction, which may be herein referred to collectively as gates 302 and individually as gate 302a, gate 302b, etc.

In the example shown in FIG. 3A and FIG. 3B, the integrated circuit 300 also includes an active region 304. Within the active region, the gates 302 contain channels that extend in the X direction through the gate structures and that electrically couple to S/D structures on either side of the gate structures. In some aspects, the S/D structures comprise EPI structures.

In the example shown in FIG. 3A, the integrated circuit 300 includes a set of FS routing tracks, labeled 306a through 306d, extending in the X direction and spaced apart from each other in the Y direction, which may be herein referred to collectively as FS tracks 306 and individually as FS track 306a, FS track 306b, etc. In some aspects, each FS routing track may comprise an FM0 conductor. The integrated circuit 300 also includes a FSDC 308 and a set of FSVs, labeled 310a through 310b, which may be herein referred to collectively as FSVs 310 and individually as FSV 310a, FSV 310b, etc. The integrated circuit 300 also includes a deep trench via 311 that extends in the X direction. The integrated circuit 300 also includes a direct vertical connector (DVC) 312 located between an S/D region of a top FET and an S/D region of a bottom FET in a CFET pair.

In the example shown in FIG. 3B, the integrated circuit 300 includes a set of backside (BS) routing tracks, labeled 314a through 314d, extending in the X direction and spaced apart from each other in the Y direction, which may be herein referred to collectively as BS tracks 314 and individually as BS track 314a, BS track 314b, etc. In some aspects, each BS routing track may comprise an BMO conductor. The integrated circuit 300 also includes a set of BSDCs, labeled 316a through 316b, which may be herein referred to collectively as BSDCs 316 and individually as BSDC 316a, BSDC 316b, etc. The integrated circuit 300 also includes a set of BSVs, labeled 318a through 318b, which may be herein referred to collectively as BSVs 318 and individually as BSV 318a, BSV 318b, etc. The location of the DVC 312 is shown in FIG. 3B as a dotted outline. FIG. 3A and FIG. 3B include markings to show the location of cross-section B-B.

FIG. 3C is a cross-sectional view of integrated circuit 300 along cut line B-B, according to aspects of the disclosure. FIG. 3C shows the relative locations of FS tracks 306a-d, DVC 312, BS tracks 314a-d, BSDC 316a, and BSV 318a. As seen in FIG. 3C, gate 302a, which is a gate-all-around (GAA) gate structure, includes stacks of nanosheet channels that make up a bottom FET and a top FET. In some aspects, the bottom FET may be an NFET and the top FET may be a PFET (or vice-versa) of a CFET pair. FIG. 3C shows a first S/D region 320 associated with the top FET and a second S/D region 322 associated with the bottom FET. In this image, the gate 302a as well as the nanosheet channels of the top FET and the bottom FET are out of the plane of the cross section, and so these are depicted with dotted outlines. Similarly, elements that are optional (and included for instructive purposes), such as the locations of the possible vias, are also depicted with dotted lines. The top and bottom FETs are shown in FIG. 3C as having two nano-sheets, but the same principles described herein may be applied to FETs having other numbers of nano-sheets.

As shown in FIG. 3C, the DVC 312 provides an electrical connection between the S/D region 320 and the S/D region 322 without the need for an FSDC or a BSDC (although an FSDC or BSDC may be required for connections to one or more FS or BS tracks). In some aspects, the CFET pair may be two parts of an inverter, in which case the DVC 312 may be the output of the inverter. In FIG. 3C, this output is connected to BS track 314c via BSDC 316a and BSV 318a, and may instead or additionally be connected to FS track 306b, FS track 306c, BS track 314b, etc., using the possible vias shown in FIG. 3C (and an FSDC, if needed). In this figure and other figures that show possible via locations, it is noted that the example locations shown are illustrative and not limiting.

It is noted that while the integrated circuit 300 has two FSVs 310 and two BSVs 318, the number of possible vias, omitted in FIGS. 3A-3C for clarity, may be much larger. For example, in FIG. 3A, an FSV may be placed above each gate 302 and FSDC 308, and a BSV may be placed below each gate 302 and BSDC 316.

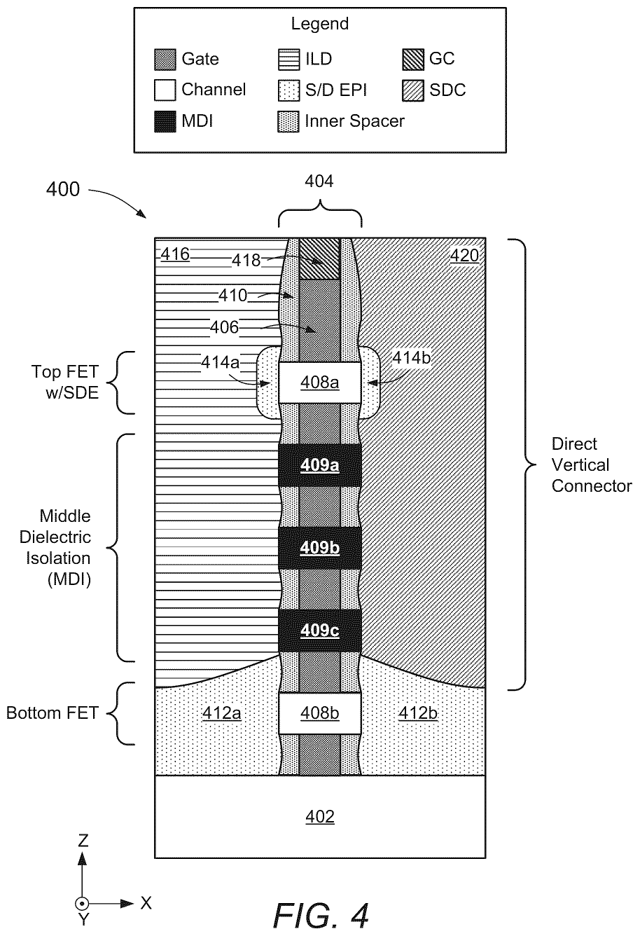

FIG. 4 is a cross-sectional view of integrated circuit 400 comprising a substrate 402 upon which a gate structure 404 has been fabricated, according to aspects of the disclosure. FIG. 4 shows a cross section of a gate that extends in the Y direction, that is spaced apart from other gates in the X direction, and that comprises metal gate structure 406. A plurality of channels extend in the X direction through the gate structure 406 and are spaced apart from each other in the Z direction. The channels, which are labelled 408a and 408b in FIG. 4, may be herein referred to collectively as channels 408. A plurality of middle dielectric isolation (MDI) structures extend in the X direction through the gate structure 406 and are spaced apart from each other in the Z direction. The MDI structures, which are labelled 409a through 409c in FIG. 4, may be herein referred to collectively as MDI structures 409. The channels 408 and MDI structures 409 extend through both the metal gate structure 406 and an insulating material that forms an inner spacer 410 that coats the metal gate structure 406. In the example shown in FIG. 4, channel 408a is part of a top FET, channel 408e is part of a bottom FET, and MDI structures 409a-c separate the top FET from the bottom FET and isolate one from the other.

In the example shown in FIG. 4, bottom EPI structures 412a and 412b form the S/D regions for the bottom FET channel 408c. Small, discontinuous EPI (SDE) structures 414a and 414b form the S/D regions for the top FET channel 408a. In the example shown in FIG. 4, the space between the gate structure 404 and structures to the left or right of gate structure 404 is filled with an interlayer dielectric (ILD) 416, and a gate contact 418 makes an electrical connection to the gate structure 404. In the example shown in FIG. 4, a direct vertical connector (DVC) 420 electrically connects the top EPI structure 414b to the bottom EPI structure 412b.

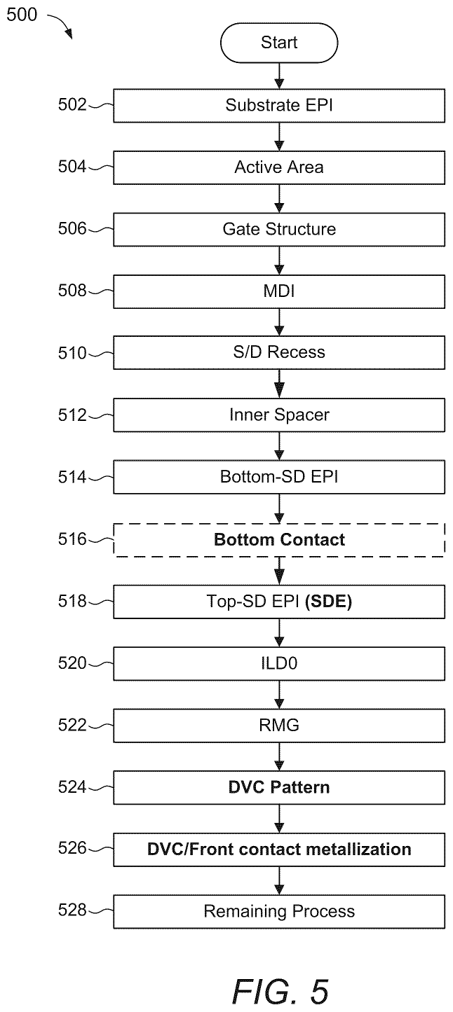

FIG. 5 is a flowchart showing a portion of a simplified wafer process for fabricating the structure shown in FIG. 4, according to aspects of the disclosure. As shown in FIG. 5, the process 500 may include, at block 502, forming the substrate EPI, e.g., the substrate 402 shown in FIG. 4. The process 500 may include, at block 504, forming the active area. The process 500 may include, at block 506, forming the gate structure(s), e.g., the gate structure 404 in FIG. 4. The process 500 may include, at block 508, forming the MDI, e.g., the channels 408b-d in FIG. 4. The process 500 may include, at block 510, forming the S/D recess, e.g., the volumes to the left and right of gate structure 404 in FIG. 4. The process 500 may include, at block 512, forming the inner spacer, e.g., the inner spacer 410 in FIG. 4. The process 500 may include, at block 514, forming the bottom S/D EPI structure, e.g., the EPI structures 412a and 412b in FIG. 4.

As further shown in FIG. 5, in some aspects, the process 500 may include, at block 516, the optional step of forming a bottom contact. The process 500 may include, at block 518, forming the top S/D EPI structure, which is an SDE that does not fill the space between one gate structure and another and thus contacts the channels of only one gate. The process 500 may include, at block 520, depositing the zero-layer ILD (ILD0), e.g., the ILD 416 in FIG. 5. The process 500 may include, at block 522, forming the replacement metal gate (RMG), e.g., the metal gate structure 406 in FIG. 4.

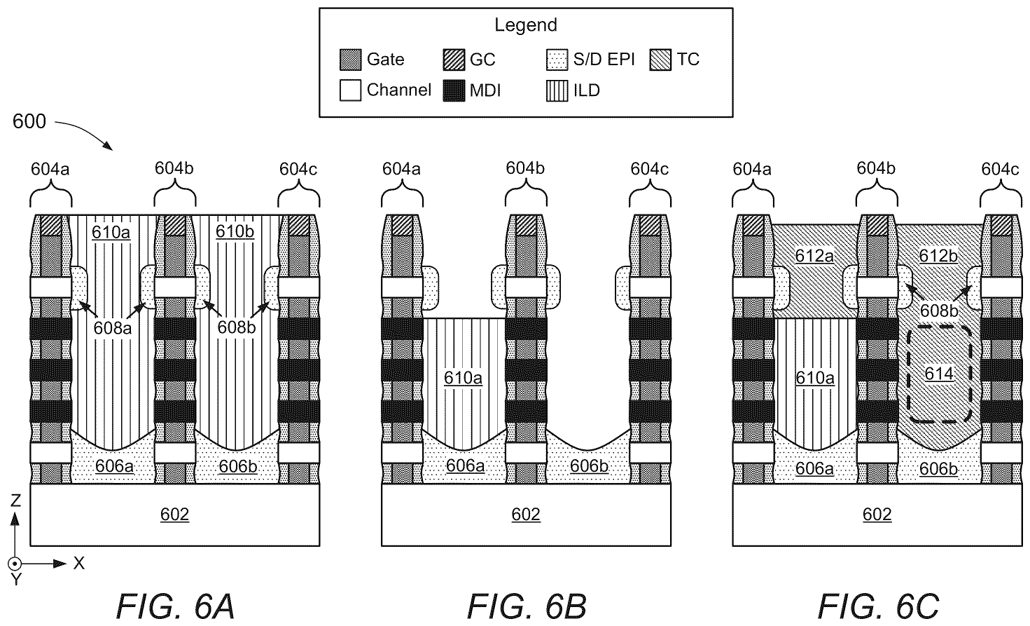

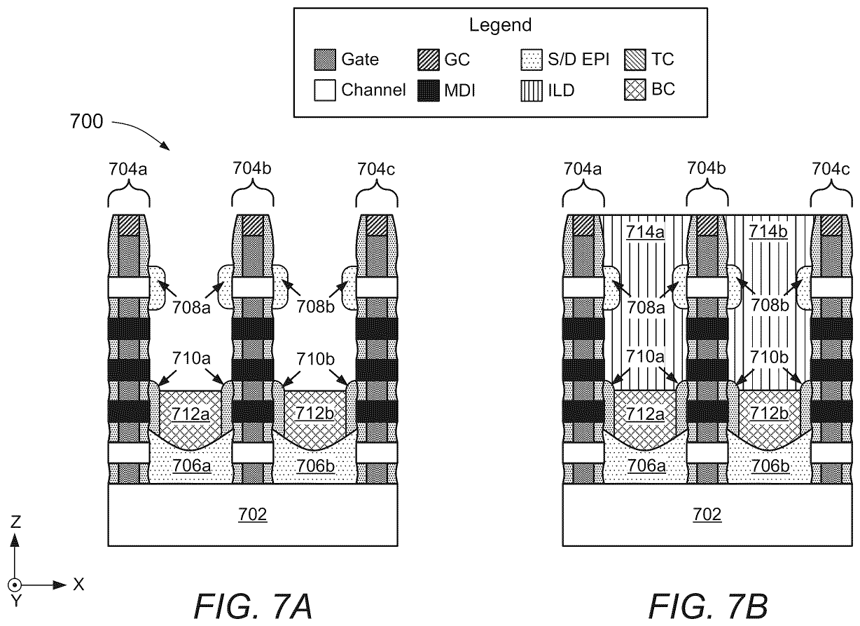

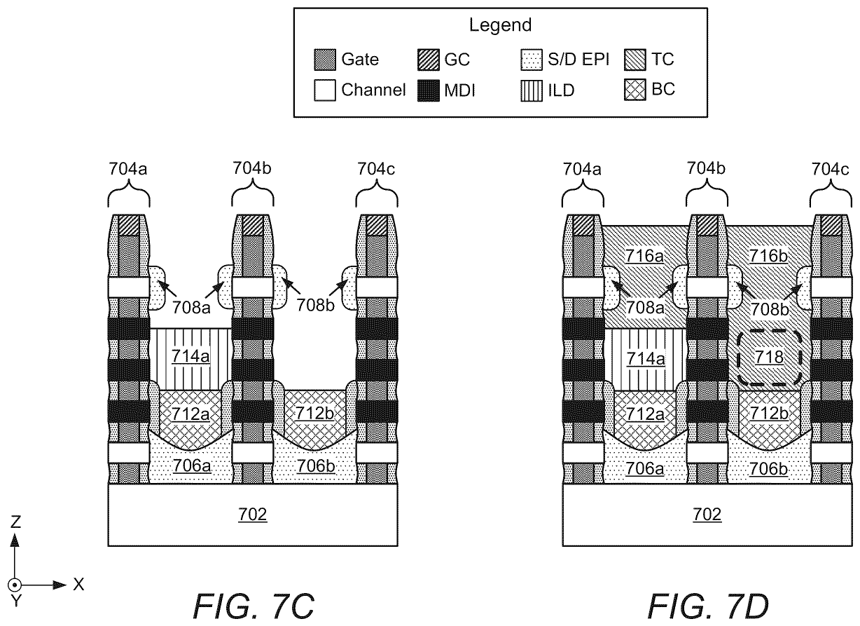

As further shown in FIG. 5, the process 500 may include, at block 524, patterning and etching to form a direct vertical connector (DVC), which may be referred to as “DVC patterning.” The process 500 may include, at block 526, DVC and front contact metallization. The remaining process steps at then performed, shown as block 528. The results of the DVC-related process steps described in FIG. 5 are shown more clearly in FIGS. 6A-C, which illustrate a structure formed when the optional block 516 is omitted, and in FIGS. 7A-D, which illustrate a structure formed with the optional block 516 is performed.

FIG. 6A, FIG. 6B, and FIG. 6C are cross-sectional views of integrated circuit 600 during steps of a process for fabricating a DVC between FETs in a CFET stack, according to aspects of the disclosure. Portions of this process may also be referred to herein as a direct vertical connector (DVC) process. In the example shown in FIGS. 6A-C, the process starts with a substrate 602 upon which multiple gates, labeled 604a through 604c. have been fabricated. The gates, which have a height in the Z direction, extend in the Y direction, and are spaced apart from each other in the X direction, may be herein referred to collectively as gates 604 and individually as gate 604a, gate 604b, etc.

FIG. 6A shows the results after the following steps: lower S/D EPI regions, S/D EPI region 606a and S/D EPI region 606b, have been created; SDE regions, SDE 608a and SDE 608b, have been created; and the space between gates have been filled with an ILD to create a first ILD volume 610a and a second ILD volume 610b.

FIG. 6B shows the results after a DVC patterning and etch process that removed the second ILD volume 610b completely so that a top FET front S/D contact (TC) can be formed there, then removed a portion of the first ILD volume 610a to create a recess so that a TC can be formed there as well.

FIG. 6C shows the results after deposition of a contact material to create a first TC 612a and a second TC 612b. Examples of contact material include, but are not limited to, contact metal, which may be a strained metal (e.g., tensile tungsten), which could be deposited to boost NFET drive. Because the second TC 612b extends down to the lower S/D EPI region 606b, the TC 612b electrically connects the lower S/D EPI region 606b to the SDE region 608b. The portion identified in FIG. 6C using a dashed outline comprises a direct vertical connector (DVC) 614, such as the DVC 512 in FIG. 5C.

FIG. 7A, FIG. 7B, FIG. 7C, and FIG. 7D are cross-sectional views of integrated circuit 700 during steps of another process for fabricating a DVC between FETs in a CFET stack, according to aspects of the disclosure. Portions of this process may also be referred to herein as a direct vertical connector (DVC) process. In the example shown in FIGS. 7A-D. the process starts with a substrate 702 upon which multiple gates, labeled 704a through 704c, have been fabricated. The gates, which have a height in the Z direction, extend in the Y direction, and are spaced apart from each other in the X direction, may be herein referred to collectively as gates 704 and individually as gate 704a, gate 704b, etc.

FIG. 7A shows the results after the following steps: lower S/D EPI regions, e.g., a first S/D EPI region 706a and a second S/D EPI region 706b, have been created; SDE regions, e.g., a first SDE region 708a and a second SDE region 708b, have been created; dielectric regions e.g., dielectric regions 710a and dielectric regions 710b are formed; and bottom FET front contacts (BCs), e.g., a first BC 712a and a second BC 712b, have been created. In some aspects, the BCs may be comprised of a tensile tungsten or another strained metal, including, but not limited to, tungsten, cobalt, molybdenum, etc.

FIG. 7B shows the results after the creation of a first ILD volume, shown as a first ILD volume 714a and a second ILD volume 714b, are formed between the gates 704. In some aspects, the ILD may comprise a dielectric, including, but not limited to, SiO₂, SiN, or SiCON.

FIG. 7C shows the results after a DVC patterning and etch process that removed the second ILD volume 714b completely so that a TC can be formed there, then removed a portion of the first ILD volume 714a to create a recess so that a TC can be formed there as well.

FIG. 7D shows the results after creation of a first TC 716a and a second TC 716b. Because the second TC 716b extends down to the BC 712b, the second TC 716b electrically connects the second S/D EPI region 706b to the second SDE region 708b. The portion identified in FIG. 7C using a dashed outline comprises a DVC 718, such as the DVC 512 in FIG. 5C.

In the examples illustrated in FIGS. 6A-C and FIGS. 7A-D, the top and bottom FETs are shown as having one channel, but the same principles may be applied to FETs having more than one channel. In some aspects, the bottom FET will have regular S/D EPI growth where the EPI will join and form a continuous volume between the gates, e.g., lower EPI regions 606a, 606b, 706a, and 706b. In some aspects, the bottom FETs may be PFETs, to maximize strain to the channel. In some aspects, small EPI structures (SDEs) are grown on the top FET so that the EPI regions from adjacent gates do not grow and join together, but instead leave space for the DVC metallization. In some aspects, NFET EPI does not contribute strain to the channel, so the small EPI volume will not cause a reduction in channel mobility. In some aspects, a strained metal (e.g., tensile tungsten), could be deposited to boost the NFET drive characteristics.

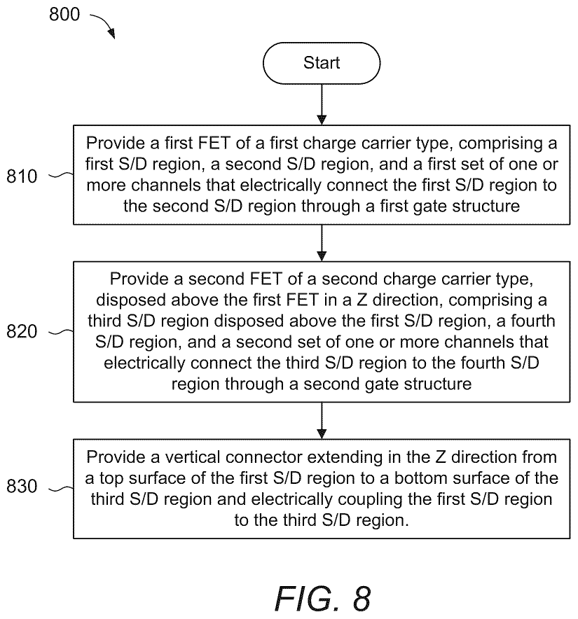

FIG. 8 is a flowchart of an example process 800 associated with fabrication of CFET circuits with direct vertical connectors, according to aspects of the disclosure.

As shown in FIG. 8, process 800 may include, at block 810, providing a first FET of a first charge carrier type, comprising a first S/D region, a second S/D region, and a first set of one or more channels that electrically connect the first S/D region to the second S/D region through a first gate structure.

As further shown in FIG. 8, process 800 may include, at block 820, providing a second FET of a second charge carrier type, disposed above the first FET in a Z direction, comprising a third S/D region disposed above the first S/D region, a fourth S/D region, and a second set of one or more channels that electrically connect the third S/D region to the fourth S/D region through a second gate structure.

As further shown in FIG. 8, process 800 may include, at block 830, providing a vertical connector extending in the Z direction from a top surface of the first S/D region to a bottom surface of the third S/D region and electrically coupling the first S/D region to the third S/D region.

In some aspects, providing the first FET comprises providing a GAA FET comprising a first GAA region and wherein providing the second FET comprises providing a GAA FET comprising a second GAA region.

In some aspects, process 800 includes providing the first FET comprises providing a first plurality of nanosheet channels extending in the X direction and spaced apart from each other in the Z direction to from a first vertical stack, each channel electrically coupling the first S/D region to the second S/D region through the first GAA region and being separated from the first GAA region by a first dielectric material, and providing the second FET comprises providing a plurality of nanosheet channels extending in the X direction and spaced apart from each other in the Z direction to from a second vertical stack disposed above the first vertical stack in the Z direction, each channel electrically coupling the third S/D region to the fourth S/D region through the second GAA region and being separated from the second GAA region by a second dielectric material.

In some aspects, providing each of the first S/D region and the second S/D region comprises providing an epitaxial structure that extends in an X direction to an adjacent gate structure and wherein providing each of the third S/D region and the fourth S/D region comprises providing a small, discontinuous epitaxial (SDE) structure that extends in an X direction a distance less than a distance to an adjacent gate structure.

In some aspects, providing the vertical connector comprises providing a bottom portion comprising a first material, and providing a top portion comprising a second material, disposed above and in contact with the bottom portion.

In some aspects, providing the bottom portion comprises providing a bottom contact material and wherein providing the top portion comprises providing a top contact material.

In some aspects, providing the vertical connector comprises providing a first material.

In some aspects, providing the first material comprises providing a bottom contact material or providing a top contact material.

In some aspects, process 800 includes providing an FM layer disposed above the first FET in the Z direction and comprising a plurality of FM conductors extending in an X direction and spaced apart from each other in a Y direction, and providing a BM layer disposed below the second FET in the Z direction and comprising a plurality of BM conductors extending in the X direction and spaced apart from each other in the Y direction.

In some aspects, providing the plurality of FM conductors extending in the X direction consists of providing four or fewer FM conductors extending in the X direction.

In some aspects, providing the plurality of BM conductors extending in the X direction consists of providing four or fewer BM conductors extending in the X direction.

In some aspects, providing the plurality of FM conductors extending in the X direction consists of providing three or fewer FM conductors extending in the X direction.

In some aspects, providing the plurality of BM conductors extending in the X direction consists of providing three or fewer BM conductors extending in the X direction.

Process 800 may include additional implementations, such as any single implementation or any combination of implementations described below and/or in connection with one or more other processes described elsewhere herein. Although FIG. 8 shows example blocks of process 800, in some implementations, process 800 may include additional blocks, fewer blocks, different blocks, or differently arranged blocks than those depicted in FIG. 8. Additionally, or alternatively, two or more of the blocks of process 800 may be performed in parallel.

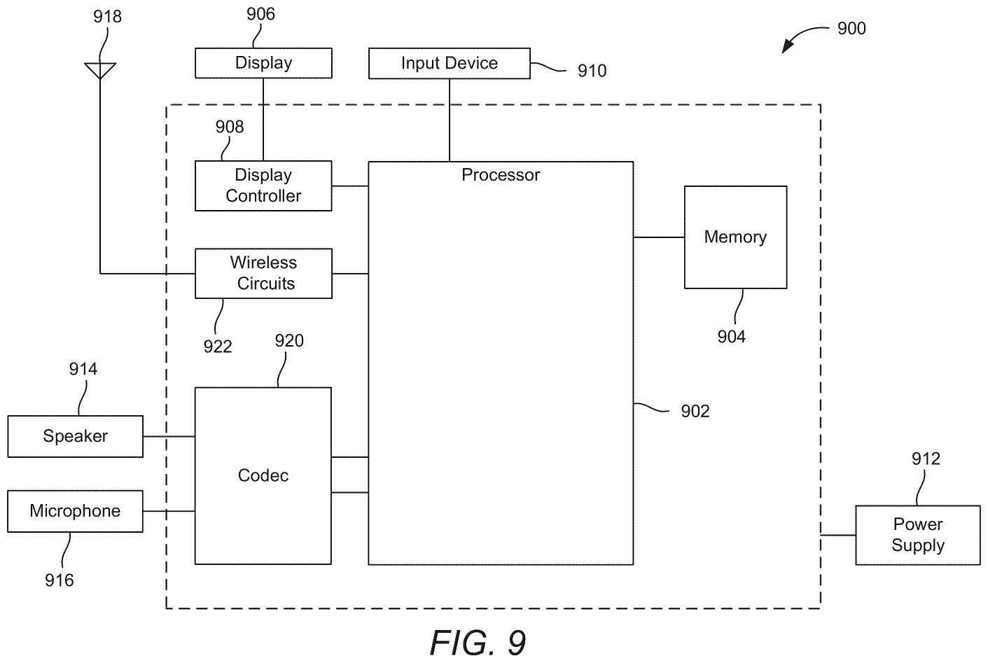

FIG. 9 illustrates a mobile device 900, according to aspects of the disclosure. In some aspects, the mobile device 900 may be implemented by including one or more IC devices manufactured based on the examples described in this disclosure.

In some aspects, mobile device 900 may be configured as a wireless communication device. As shown, mobile device 900 includes processor 902. Processor 902 may be communicatively coupled to memory 904 over a link, which may be a die-to-die or chip-to-chip link. Mobile device 900 also includes display 906 and display controller 908, with display controller 908 coupled to processor 902 and to display 906. The mobile device 900 may include input device 910 (e.g., physical, or virtual keyboard), power supply 912 (e.g., battery), speaker 914, microphone 916, and wireless antenna 918. In some aspects, the power supply 912 may directly or indirectly provide the supply voltage for operating some or all of the components of the mobile device 900.

In some aspects, FIG. 9 may include coder/decoder (CODEC) 920 (e.g., an audio and/or voice CODEC) coupled to processor 902; speaker 914 and microphone 916 coupled to CODEC 920; and wireless circuits 922 (which may include a modem, RF circuitry, filters, etc.) coupled to wireless antenna 918 and to processor 902.

In some aspects, one or more of processor 902, display controller 908, memory 904, CODEC 920, and wireless circuits 922 may include one or more IC devices including semiconductor structures manufactured according to the examples described in this disclosure.

It should be noted that although FIG. 9 depicts a mobile device 900, similar architecture may be used to implement an apparatus including a set top box, a music player, a video player, an entertainment unit, a navigation device, a personal digital assistant (PDA), a fixed location data unit, a computer, a laptop, a tablet, a communications device, a mobile phone, or other similar devices.

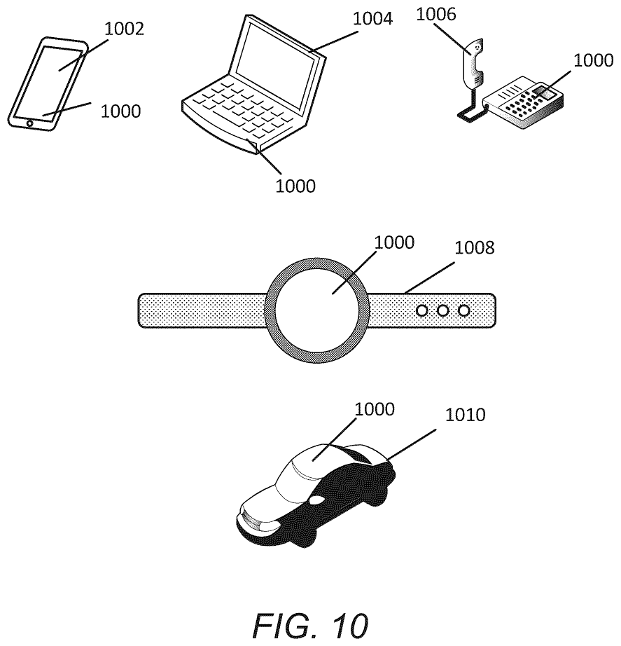

FIG. 10 illustrates various electronic devices that may be integrated with any of the aforementioned devices, semiconductor devices, integrated circuit (IC) packages, integrated circuit (IC) devices, semiconductor devices, integrated circuits, electronic components, interposer packages, package-on-package (POP), System in Package (SiP), or System on Chip (SoC), according to aspects of the disclosure. For example, a mobile phone device 1002, a laptop computer device 1004, a fixed location terminal device 1006, a wearable device 1008, or automotive vehicle 1010 may include a semiconductor device 1000 (which may include integrated circuits 400 and 500) as described herein. The devices 1002, 1004, 1006 and 1008 and the vehicle 1010 illustrated in FIG. 10 are merely exemplary. Other apparatuses or devices may also feature the semiconductor device 1000 including, but not limited to, a group of devices that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

The foregoing disclosed devices and functionalities may be designed and configured into computer files (e.g., RTL, GDSII, GERBER, etc.) stored on computer-readable media. Some or all such files may be provided to fabrication handlers who fabricate devices based on such files. Resulting products may include semiconductor wafers that are then cut into semiconductor die and packaged into an antenna on glass device. The antenna on glass device may then be employed in devices described herein.

In the detailed description above it can be seen that different features are grouped together in examples. This manner of disclosure should not be understood as an intention that the example clauses have more features than are explicitly mentioned in each clause. Rather, the various aspects of the disclosure may include fewer than all features of an individual example clause disclosed. Therefore, the following clauses should hereby be deemed to be incorporated in the description, wherein each clause by itself can stand as a separate example. Although each dependent clause can refer in the clauses to a specific combination with one of the other clauses, the aspect(s) of that dependent clause are not limited to the specific combination. It will be appreciated that other example clauses can also include a combination of the dependent clause aspect(s) with the subject matter of any other dependent clause or independent clause or a combination of any feature with other dependent and independent clauses. The various aspects disclosed herein expressly include these combinations, unless it is explicitly expressed or can be readily inferred that a specific combination is not intended (e.g., contradictory aspects, such as defining an element as both an electrical insulator and an electrical conductor). Furthermore, it is also intended that aspects of a clause can be included in any other independent clause, even if the clause is not directly dependent on the independent clause.

Implementation examples are described in the following numbered clauses:
Clause 1. A semiconductor structure, comprising: a first field effect transistor (FET) of a first charge carrier type, comprising a first source/drain (S/D) region, a second S/D region, and a first set of one or more channels that electrically connect the first S/D region to the second S/D region through a first gate structure; a second FET of a second charge carrier type, disposed above the first FET in a Z direction and comprising a third S/D region disposed above the first S/D region, a fourth S/D region, and a second set of one or more channels that electrically connect the third S/D region to the fourth S/D region through a second gate structure; and a vertical connector extending in the Z direction from a top surface of the first S/D region to a bottom surface of the third S/D region and electrically coupling the first S/D region to the third S/D region.
Clause 2. The semiconductor structure of clause 1, wherein the first gate structure comprises a first gate-all-around (GAA) structure comprising a first GAA region and wherein the second gate structure comprises a second GAA structure comprising a second GAA region.
Clause 3. The semiconductor structure of clause 2, wherein: the first FET comprises a first plurality of nanosheet channels extending in an X direction, spaced apart from each other in the Z direction to from a first vertical stack, electrically coupling the first S/D region to the second S/D region through the first GAA region, and being separated from the first GAA region by a first dielectric material; and the second FET comprises a second plurality of nanosheet channels extending in the X direction, spaced apart from each other in the Z direction to from a second vertical stack disposed above the first vertical stack in the Z direction, electrically coupling the third S/D region to the fourth S/D region through the second GAA region, and being separated from the second GAA region by a second dielectric material.
Clause 4. The semiconductor structure of any of clauses 1 to 3, wherein each of the first S/D region and the second S/D region comprises an epitaxial structure that extends in an X direction to an adjacent gate structure and wherein each of the third S/D region and the fourth S/D region comprises a small, discontinuous epitaxial (SDE) structure that extends in the X direction a distance less than a distance to the adjacent gate structure.
Clause 5. The semiconductor structure of any of clauses 1 to 4, wherein the vertical connector comprises a bottom portion comprising a first material, and a top portion comprising a second material, disposed above and in contact with the bottom portion.
Clause 6. The semiconductor structure of clause 5, wherein the bottom portion comprises a bottom contact material and wherein the top portion comprises a top contact material.
Clause 7. The semiconductor structure of any of clauses 1 to 6, wherein the vertical connector comprises a first material.
Clause 8. The semiconductor structure of clause 7, wherein the first material comprises a bottom contact material or a top contact material.
Clause 9. The semiconductor structure of clause 8, wherein the first material comprises at least one of tungsten, cobalt, or molybdenum.
Clause 10. The semiconductor structure of any of clauses 1 to 9, further comprising: a frontside metal (FM) layer disposed above the first FET in the Z direction and comprising a plurality of FM conductors extending in an X direction and spaced apart from each other in a Y direction; and a backside metal (BM) layer disposed below the second FET in the Z direction and comprising a plurality of BM conductors extending in the X direction and spaced apart from each other in the Y direction.
Clause 11. The semiconductor structure of clause 10, wherein the plurality of FM conductors extending in the X direction consists of four or fewer FM conductors extending in the X direction.
Clause 12. The semiconductor structure of any of clauses 10 to 11, wherein the plurality of BM conductors extending in the X direction consists of four or fewer BM conductors extending in the X direction.
Clause 13. The semiconductor structure of any of clauses 10 to 12, wherein the plurality of FM conductors extending in the X direction consists of three or fewer FM conductors extending in the X direction.
Clause 14. The semiconductor structure of any of clauses 10 to 13, wherein the plurality of BM conductors extending in the X direction consists of three or fewer BM conductors extending in the X direction.
Clause 15. A method of fabricating a semiconductor structure, the method comprising: providing a first field effect transistor (FET) of a first charge carrier type, comprising providing a first source/drain (S/D) region, providing a second S/D region, and providing a first set of one or more channels that electrically connect the first S/D region to the second S/D region through a first gate structure; providing a second FET of a second charge carrier type, disposed above the first FET in a Z direction, comprising providing a third S/D region disposed above the first S/D region, providing a fourth S/D region, and providing a second set of one or more channels that electrically connect the third S/D region to the fourth S/D region through a second gate structure; and providing a vertical connector extending in the Z direction from a top surface of the first S/D region to a bottom surface of the third S/D region and electrically coupling the first S/D region to the third S/D region.
Clause 16. The method of clause 15, wherein providing the first FET comprises providing a gate-all-around (GAA) FET comprising a first GAA region and wherein providing the second FET comprises providing a GAA FET comprising a second GAA region.
Clause 17. The method of clause 16, wherein: providing the first FET comprises providing a first plurality of nanosheet channels extending in an X direction, spaced apart from each other in the Z direction to from a first vertical stack, electrically coupling the first S/D region to the second S/D region through the first GAA region, and being separated from the first GAA region by a first dielectric material; and providing the second FET comprises providing a plurality of nanosheet channels extending in the X direction, spaced apart from each other in the Z direction to from a second vertical stack disposed above the first vertical stack in the Z direction, electrically coupling the third S/D region to the fourth S/D region through the second GAA region, and being separated from the second GAA region by a second dielectric material.
Clause 18. The method of any of clauses 15 to 17, wherein providing each of the first S/D region and the second S/D region comprises providing an epitaxial structure that extends in an X direction to an adjacent gate structure and wherein providing each of the third S/D region and the fourth S/D region comprises providing a small, discontinuous epitaxial (SDE) structure that extends in the X direction a distance less than a distance to the adjacent gate structure.
Clause 19. The method of any of clauses 15 to 18, wherein providing the vertical connector comprises providing a bottom portion comprising a first material, and providing a top portion comprising a second material, disposed above and in contact with the bottom portion.
Clause 20. The method of clause 19, wherein providing the bottom portion comprises providing a bottom contact material and wherein providing the top portion comprises providing a top contact material.
Clause 21. The method of any of clauses 15 to 20, wherein providing the vertical connector comprises providing a first material.
Clause 22. The method of clause 21, wherein providing the first material comprises providing a bottom contact material or providing a top contact material.
Clause 23. The method of clause 22, wherein providing the first material comprises providing at least one of tungsten, cobalt, or molybdenum.
Clause 24. The method of any of clauses 15 to 23, further comprising: providing a frontside metal (FM) layer disposed above the first FET in the Z direction and comprising a plurality of FM conductors extending in an X direction and spaced apart from each other in a Y direction; and providing a backside metal (BM) layer disposed below the second FET in the Z direction and comprising a plurality of BM conductors extending in the X direction and spaced apart from each other in the Y direction.
Clause 25. The method of clause 24, wherein providing the plurality of FM conductors extending in the X direction consists of providing four or fewer FM conductors extending in the X direction.
Clause 26. The method of any of clauses 24 to 25, wherein providing the plurality of BM conductors extending in the X direction consists of providing four or fewer BM conductors extending in the X direction.
Clause 27. The method of any of clauses 24 to 26, wherein providing the plurality of FM conductors extending in the X direction consists of providing three or fewer FM conductors extending in the X direction.
Clause 28. The method of any of clauses 24 to 27, wherein providing the plurality of BM conductors extending in the X direction consists of providing three or fewer BM conductors extending in the X direction.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those of skill in the art will appreciate that the various illustrative logical blocks, modules, circuits, and algorithm steps described in connection with the aspects disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a general purpose processor, a DSP, an ASIC, an FPGA, or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The methods, sequences and/or algorithms described in connection with the aspects disclosed herein may be embodied directly in hardware, in a software module executed by a processor, or in a combination of the two. A software module may reside in random access memory (RAM), flash memory, read-only memory (ROM), erasable programmable ROM (EPROM), electrically erasable programmable ROM (EEPROM), registers, hard disk, a removable disk, a CD-ROM, or any other form of storage medium known in the art. An example storage medium is coupled to the processor such that the processor can read information from, and write information to, the storage medium. In the alternative, the storage medium may be integral to the processor. The processor and the storage medium may reside in an ASIC. The ASIC may reside in a user terminal (e.g., UE). In the alternative, the processor and the storage medium may reside as discrete components in a user terminal.

In one or more example aspects, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

While the foregoing disclosure shows illustrative aspects of the disclosure, it should be noted that various changes and modifications could be made herein without departing from the scope of the disclosure as defined by the appended claims. The functions, steps and/or actions of the method claims in accordance with the aspects of the disclosure described herein need not be performed in any particular order. Furthermore, although elements of the disclosure may be described or claimed in the singular, the plural is contemplated unless limitation to the singular is explicitly stated.

What is claimed is:

1. A semiconductor structure, comprising:
a first field effect transistor (FET) of a first charge carrier type, comprising a first source/drain (S/D) region, a second S/D region, and a first set of one or more channels that electrically connect the first S/D region to the second S/D region through a first gate structure;
a second FET of a second charge carrier type, disposed above the first FET in a Z direction and comprising a third S/D region disposed above the first S/D region, a fourth S/D region, and a second set of one or more channels that electrically connect the third S/D region to the fourth S/D region through a second gate structure; and
a vertical connector extending in the Z direction from a top surface of the first S/D region to a bottom surface of the third S/D region and electrically coupling the first S/D region to the third S/D region.

2. The semiconductor structure of claim 1, wherein the first gate structure comprises a first gate-all-around (GAA) structure comprising a first GAA region and wherein the second gate structure comprises a second GAA structure comprising a second GAA region.

3. The semiconductor structure of claim 2, wherein:
the first FET comprises a first plurality of nanosheet channels extending in an X direction, spaced apart from each other in the Z direction to from a first vertical stack, electrically coupling the first S/D region to the second S/D region through the first GAA region, and being separated from the first GAA region by a first dielectric material; and
the second FET comprises a second plurality of nanosheet channels extending in the X direction, spaced apart from each other in the Z direction to from a second vertical stack disposed above the first vertical stack in the Z direction, electrically coupling the third S/D region to the fourth S/D region through the second GAA region, and being separated from the second GAA region by a second dielectric material.

4. The semiconductor structure of claim 1, wherein each of the first S/D region and the second S/D region comprises an epitaxial structure that extends in an X direction to an adjacent gate structure and wherein each of the third S/D region and the fourth S/D region comprises a small, discontinuous epitaxial (SDE) structure that extends in the X direction a distance less than a distance to the adjacent gate structure.

5. The semiconductor structure of claim 1, wherein the vertical connector comprises a bottom portion comprising a first material, and a top portion comprising a second material, disposed above and in contact with the bottom portion.

6. The semiconductor structure of claim 5, wherein the bottom portion comprises a bottom contact material and wherein the top portion comprises a top contact material.

7. The semiconductor structure of claim 1, wherein the vertical connector comprises a first material.

8. The semiconductor structure of claim 7, wherein the first material comprises a bottom contact material or a top contact material.

9. The semiconductor structure of claim 8, wherein the first material comprises at least one of tungsten, cobalt, or molybdenum.

10. The semiconductor structure of claim 1, further comprising:
a frontside metal (FM) layer disposed above the first FET in the Z direction and comprising a plurality of FM conductors extending in an X direction and spaced apart from each other in a Y direction; and
a backside metal (BM) layer disposed below the second FET in the Z direction and comprising a plurality of BM conductors extending in the X direction and spaced apart from each other in the Y direction.

11. The semiconductor structure of claim 10, wherein the plurality of FM conductors extending in the X direction consists of four or fewer FM conductors extending in the X direction.

12. The semiconductor structure of claim 10, wherein the plurality of BM conductors extending in the X direction consists of four or fewer BM conductors extending in the X direction.

13. The semiconductor structure of claim 10, wherein the plurality of FM conductors extending in the X direction consists of three or fewer FM conductors extending in the X direction.

14. The semiconductor structure of claim 10, wherein the plurality of BM conductors extending in the X direction consists of three or fewer BM conductors extending in the X direction.

15. A method of fabricating a semiconductor structure, the method comprising:
providing a first field effect transistor (FET) of a first charge carrier type, comprising providing a first source/drain (S/D) region, providing a second S/D region, and providing a first set of one or more channels that electrically connect the first S/D region to the second S/D region through a first gate structure;
providing a second FET of a second charge carrier type, disposed above the first FET in a Z direction, comprising providing a third S/D region disposed above the first S/D region, providing a fourth S/D region, and providing a second set of one or more channels that electrically connect the third S/D region to the fourth S/D region through a second gate structure; and
providing a vertical connector extending in the Z direction from a top surface of the first S/D region to a bottom surface of the third S/D region and electrically coupling the first S/D region to the third S/D region.

16. The method of claim 15, wherein providing the first FET comprises providing a gate-all-around (GAA) FET comprising a first GAA region and wherein providing the second FET comprises providing a GAA FET comprising a second GAA region.

17. The method of claim 16, wherein:
providing the first FET comprises providing a first plurality of nanosheet channels extending in an X direction, spaced apart from each other in the Z direction to from a first vertical stack, electrically coupling the first S/D region to the second S/D region through the first GAA region, and being separated from the first GAA region by a first dielectric material; and
providing the second FET comprises providing a plurality of nanosheet channels extending in the X direction, spaced apart from each other in the Z direction to from a second vertical stack disposed above the first vertical stack in the Z direction, electrically coupling the third S/D region to the fourth S/D region through the second GAA region, and being separated from the second GAA region by a second dielectric material.

18. The method of claim 15, wherein providing each of the first S/D region and the second S/D region comprises providing an epitaxial structure that extends in an X direction to an adjacent gate structure and wherein providing each of the third S/D region and the fourth S/D region comprises providing a small, discontinuous epitaxial (SDE) structure that extends in the X direction a distance less than a distance to the adjacent gate structure.

19. The method of claim 15, wherein providing the vertical connector comprises providing a bottom portion comprising a first material, and providing a top portion comprising a second material, disposed above and in contact with the bottom portion.

20. The method of claim 19, wherein providing the bottom portion comprises providing a bottom contact material and wherein providing the top portion comprises providing a top contact material.

21. The method of claim 15, wherein providing the vertical connector comprises providing a first material.

22. The method of claim 21, wherein providing the first material comprises providing a bottom contact material or providing a top contact material.

23. The method of claim 22, wherein providing the first material comprises providing at least one of tungsten, cobalt, or molybdenum.

24. The method of claim 15, further comprising:
providing a frontside metal (FM) layer disposed above the first FET in the Z direction and comprising a plurality of FM conductors extending in an X direction and spaced apart from each other in a Y direction; and
providing a backside metal (BM) layer disposed below the second FET in the Z direction and comprising a plurality of BM conductors extending in the X direction and spaced apart from each other in the Y direction.

25. The method of claim 24, wherein providing the plurality of FM conductors extending in the X direction consists of providing four or fewer FM conductors extending in the X direction.

26. The method of claim 24, wherein providing the plurality of BM conductors extending in the X direction consists of providing four or fewer BM conductors extending in the X direction.

27. The method of claim 24, wherein providing the plurality of FM conductors extending in the X direction consists of providing three or fewer FM conductors extending in the X direction.

28. The method of claim 24, wherein providing the plurality of BM conductors extending in the X direction consists of providing three or fewer BM conductors extending in the X direction.
